(19) United States
(12) Patent Application Publication
(10) Pub. No.: US 2004/0082103 A1
(43) Pub. Date: Apr. 29, 2004

(54) Semiconductor package with marking film and manufacturing method thereof

(75) Inventor: Yao-Hsin Feng, Hualien City (TW)

Correspondence Address: BACON & THOMAS, PLLC, 625 SLATERS LANE, FOURTH FLOOR, ALEXANDRIA, VA, 22314

(73) Assignee: Advanced Semiconductor Engineering, Inc., Kaoshiung (TW)

(21) Appl. No.: 10/690,667

(22) Filed: Oct. 23, 2003

(30) Foreign Application Priority Data
Oct. 24, 2002 (TW) 091124811

(51) Int. Cl. H01L 21/44; H01L 23/053; H01L 23/52

(52) U.S. Cl. 438/106; 257/701; 257/738; 257/790; 438/125

(57) ABSTRACT

A semiconductor package includes a substrate, a chip and a marking film. The semiconductor chip is electrically connected to the substrate. A marking film is formed on the back surface of the chip. Thereby, a mark is formed by patterning the marking film. Generally, the marking film is a dry film or a tape. Not only the marking film prevents the singulated chips from being in a fry-chip manner but also can be patterned by laser ablation instead of the conventional method of forming a mark directly on the back surface of the chip. Accordingly, the chip will be prevented from destroying in the duration of performing the marking process.

### BACKGROUND OF THE INVENTION

1. Field of Invention

This invention relates to a semiconductor package and a manufacturing method thereof. More particularly, the present invention is related to a semiconductor package with a marking film, and a manufacturing method thereof.

2. Related Art

Originally, a semiconductor package is formed by the steps of singulating a wafer into a plurality of chips, disposing one of the chips on a substrate, electrically connecting the chip and the substrate by conductive wires or conductive bumps and encapsulating the chip via an encapsulation. Generally speaking, the marking process is performed by laser ablation to pattern the surface of the encapsulation to form a mark thereon or by printing ink to form a mark on the surface of the encapsulation.

However, in a flip chip package without encapsulation covering the chip and a wafer level package, the marking process is performed by laser ablation to pattern the back surface of the chip directly. Due to the substrate formed by a material of silicon, the chip is usually damaged and cracked in the duration of performing the marking process for that the material of silicon is fragile. Besides, when the mark is not formed correctly due to the wrong layout, the mark will be not easily to erase for the reason that destroying the back surface of the chip forms the mark.

Therefore, providing another semiconductor package and a method of manufacturing thereof to solve the mentioned-above disadvantages is the most important task in this invention.

### SUMMARY OF THE INVENTION

In view of the above-mentioned problems, an objective of this invention is to provide a semiconductor package with a marking film formed on a back surface of a chip therein so as to prevent the chip from being destroyed and to provide a better method for performing a re-marking process or an erasing process.

To achieve the above-mentioned objective, a semiconductor package is provided, wherein the semiconductor package comprises at least a substrate, a chip electrically connected to the substrate, a marking film disposed on the back surface of the chip. Therein, the marking film is a film with multi-layers. And said marking film, for example a polymer layer and a polyimide layer, is not only regarded as a protective film for preventing the chip from being damaged but also provided as a patterned film for forming a mark thereon. The mark is formed by patterning the marking film instead of the process of directly destroying the back surface of the chip. Accordingly, when the mark is not formed correctly, the marking film can be removed to performing an erasing process and a re-marking process.

In addition, this invention also provides a manufacturing method of said semiconductor package. The method comprises the following steps. Firstly, a substrate and a wafer with a marking film formed on the back surface of the wafer are provided. The wafer is mounted and electrically connected to the substrate via solder bumps, and an underfill is disposed between the substrate and the wafer. Afterwards, the wafer and the substrate are singulated simultaneously to form a plurality semiconductor packages. Finally, a marking process is performed to pattern the marking film to form a mark.

As mentioned above, the marking film can be a tape or a dry film so as to prevent the fly-chip effect after singulating the wafer.

### BRIEF DESCRIPTION OF THE DRAWINGS

The invention will become more fully understood from the detailed description given herein below illustrations only, and thus are not limitative of the present invention, and wherein:

FIG. 1 is a cross-sectional view of a semiconductor package according to the first embodiment of the present invention;

FIG. 1A is a cross-sectional view of a marking film according to the first preferred embodiment of FIG. 1 before removing the release layer and the face layer;

FIG. 1B is a cross-sectional view of a marking film according to the first preferred embodiment of FIG. 1 after removing the release layer and the face layer;

FIG. 2 is a cross-sectional view of a semiconductor package according to the second embodiment of the present invention;

FIG. 3 is a cross-sectional view of a semiconductor package according to the third embodiment of the present invention; and

FIG. 4 is a flow chart illustrating the process flow of a manufacturing method of the semiconductor package of FIG. 1.

### DETAILED DESCRIPTION OF THE INVENTION

The semiconductor package according to the preferred embodiment of this invention will be described herein below with reference to the accompanying drawings, wherein the same reference numbers refer to the same elements.

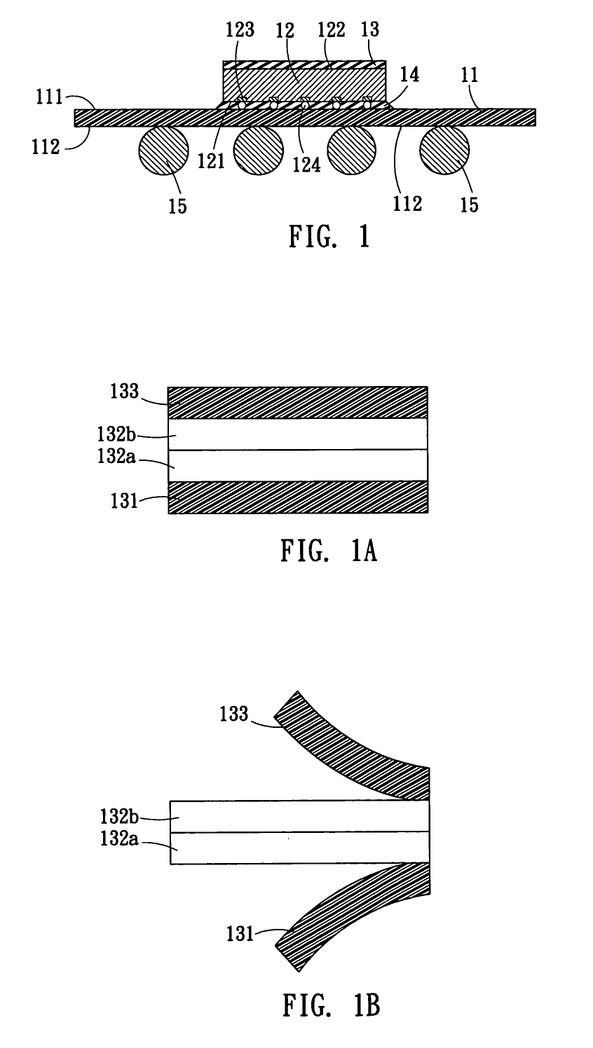

In accordance with the first preferred embodiment as shown in FIG. 1, there is provided a semiconductor package. The semiconductor package mainly comprises a substrate 11, a chip 12 and a marking film 13. The substrate 11 has an upper surface 111 and an opposite lower surface 112. The chip has an active surface 121, an opposite back surface 122, a plurality of bonding pads 123 formed on the active surface 121, a plurality of bumps 124 formed on the bonding pads 123 and a marking film 13 formed on the back surface 122 of the chip 12. The active surface 121 of the chip 12 faces the upper surface 111 of the substrate 11 and mounted to the substrate 11 via the bumps 124 in a flip chip manner. Therein, the chip 12 is a silicon chip; the marking film 13 is a film with multi-layers; and the bumps 124 are solder bumps or gold bumps. Besides, the coefficient of thermal expansion (CTE) of the substrate 11 is different from that of the chip 12. Thus, an underfill 14 is provided between the substrate 11 and the chip 12 and encapsulates the bumps 124 so as to lower the thermal stress caused by the change of working temperature and the effect of CTE mismatch between the substrate 11 and the chip 12. Moreover, a plurality of solder balls 15 are disposed on the lower surface 112 of the substrate 11 to provide electrical paths for electrically connecting to external electronic devices.

As shown in FIG. 1A, the marking film 13 originally comprises four layers. The first layer 131 is a release layer; the second layer 132a and the third layer 132b are adhesive layers; and the fourth layer 133 is a face layer. Next, referring to FIG. 1B, which shows that the first layer 131 (the release layer) and the fourth layer 133 (the face layer) are removed before attaching to the back surface 122 of the chip 12.

As mentioned above, a mark is formed according to the following steps. Firstly, the first layer 131 (the release layer) is removed so that the second layer 132a (the adhesive layer) can be directly attached to the back surface 122 of the chip 12. Next, the fourth layer 133 (the face layer) is removed to expose the third layer 132b (the adhesive layer). The second layer 132a and the third layer 132b are different from each other in color. Accordingly, when the third layer 132b is patterned to form a patterned adhesive layer, the patterned adhesive layer will expose another adhesive layer (the second layer 132a) partially to form a mark.

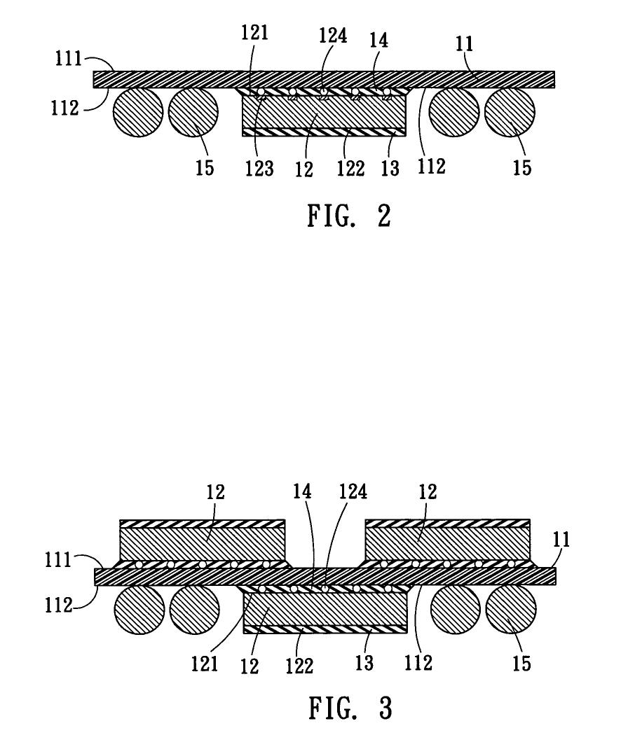

In addition, referring to FIG. 2, there is provided a second embodiment of this invention. In the second embodiment, the chip 12 is disposed on the lower surface 112 of the substrate 11. Next, referring to FIG. 3, there is provided a third embodiment of this invention. In the third embodiment, there are two chips 12 disposed on the upper surface 111 of the substrate 11 and another chip 12 mounted on the lower surface 112 of the substrate 11. Therein, each chip 12 has a marking film formed on each back surface. It also should be noted that the reference numeral of each element in FIGS. 2 and 3 corresponds to the same reference numeral of each element in FIG. 1.

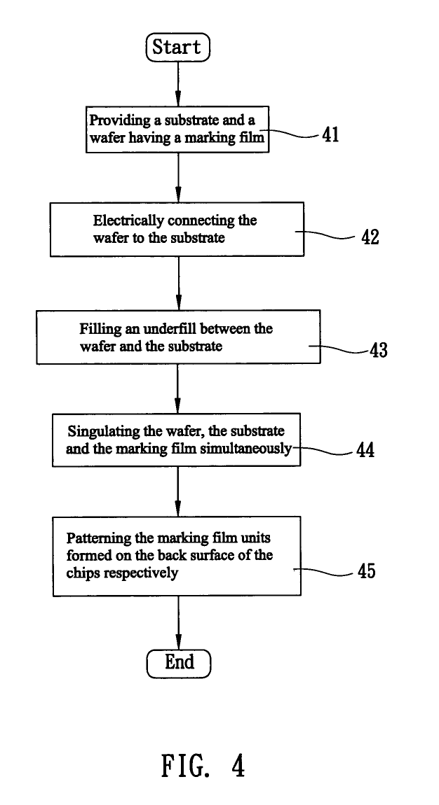

Furthermore, referring to FIG. 4, there is provided a flow chart illustrating the process flow of a manufacturing method of the semiconductor package as shown above.

Firstly, in step 41, a substrate is provided, wherein the substrate is an organic substrate or a ceramic substrate. Next, in step 42, a wafer is provided, wherein the wafer has an active surface, a plurality of bonding pads formed on the active surface, a back surface with a marking film formed on the back surface, and a plurality of solder bumps formed on the bonding pads. Then, the wafer is mounted and electrically connected to the substrate via solder bumps. And an underfill is disposed between the substrate and the wafer as shown in step 43. Next, in step 44, the wafer, the marking film and the substrate are singulated simultaneously into a plurality of chips, marking film units and substrate unit. Finally, in step 45, a marking process is performed to pattern the marking film unit on the back surface of the chip to form a mark.

As shown in step 45, the mark is formed by patterning the marking film unit instead of the process of directly destroying the back surface of the chip. Accordingly, when the mark is not formed correctly, the marking film unit can be removed to perform a re-marking process and an erasing process.

Although the invention has been described in considerable detail with reference to certain preferred embodiments, it will be appreciated and understood that various changes and modifications may be made without departing from the spirit and scope of the invention as defined in the appended claims.

What is claimed is:

1. A semiconductor package, comprising:
a substrate having an upper surface and a lower surface;
a chip having an active surface, an opposite back surface, a plurality of bonding pads formed on the active surface, a plurality of bumps formed on the bonding pads, and the chip disposed on and electrically connected to the substrate via the bumps; and
a marking film formed on the back surface of the chip.

2. The semiconductor package of claim 1, wherein the marking film is a dry film.

3. The semiconductor package of claim 1, wherein the marking film is a tape.

4. The semiconductor package of claim 1, wherein the marking film comprises a plurality of layers.

5. The semiconductor package of claim 1, wherein the marking film at least comprises a first adhesive layer and a second adhesive, and the first adhesive is different from the second adhesive layer in color.

6. The semiconductor package of claim 5, wherein the first adhesive layer is patterned to form a first patterned adhesive layer and exposes the second adhesive layer.

7. The semiconductor package of claim 6, wherein the first patterned adhesive layer is formed by laser ablation.

8. The semiconductor package of claim 1, further comprising a plurality of solder balls formed on the lower surface of the substrate.

9. The semiconductor package of claim 1, wherein the marking film is a polymer layer.

10. The semiconductor package of claim 1, wherein the marking film is made of polyimide.

11. The semiconductor package of claim 1, further comprising an underfill disposed between the substrate and the chip and encapsulating the bumps.

12. A semiconductor package manufacturing method, comprising:
providing a wafer, the wafer having an active surface, a back surface, a plurality of bonding pads formed on the active surface, a plurality of bumps formed on the bonding pads and a marking film formed on the back surface;
providing a substrate having an upper surface and a lower surface;
attaching the wafer to the substrate via the bumps;
singulating the wafer, the substrate and the marking film simultaneously so as to form a plurality of chips, substrate units and marking film units formed on the chips, respectively;
patterning one of the marking film units; and
forming a plurality of solder balls on the lower surface.

13. The semiconductor package manufacturing method of claim 12, further comprising disposing an underfill between the substrate and the wafer.

14. The semiconductor package manufacturing method of claim 12, wherein the marking film is a dry film.

15. The semiconductor package manufacturing method of claim 12, wherein the marking film is a tape.

16. The semiconductor package manufacturing method of claim 12, wherein the marking film at least comprises two adhesive layers.

17. The semiconductor package manufacturing method of claim 16, wherein one of the adhesive layers is patterned to form a patterned adhesive layer and exposes another adhesive layer.

18. The semiconductor package manufacturing method of claim 16, wherein the patterned adhesive layer is different from the other of the adhesive layers in color.

19. The semiconductor package manufacturing method of claim 16, wherein the patterned adhesive layer is formed by laser ablation.
